(19) United States
(12) Patent Application Publication
(10) Pub. No.: US 2015/0366059 A1
(43) Pub. Date: Dec. 17, 2015

(54) CIRCUIT BOARD AND METHOD OF MANUFACTURING THE SAME

(71) Applicant: SAMSUNG ELECTRO-MECHANICS CO., LTD., Suwon-Si (KR)

(72) Inventors: Seung Eun LEE, Seongnam-si (KR); Myung Sam KANG, Hwaseong-si (KR); Kwang Hee KWON, Busan (KR); Seung Yeop KOOK, Busan (KR); Se Rang IM, Suwon-Si (KR)

(21) Appl. No.: 14/731,366

(22) Filed: Jun. 4, 2015

(30) Foreign Application Priority Data
Jun. 11, 2014 (KR) 10-2014-0070914

(51) Int. Cl. H05K 1/11; H05K 3/40

(52) U.S. Cl. CPC H05K 1/111; H05K 3/40

(57) ABSTRACT

A seed layer and a resist layer are formed on a solder resist layer, and the resist layer is patterned to form connection pads and pad plating layers. Then, the resist layer is removed, and the seed layer exposed to the outside is removed. A device may be mounted on this circuit board, and a connection terminal of the device and the connection pad of the circuit board may be connected to each other by a wire, or the like.

### CROSS REFERENCE(S) TO RELATED APPLICATIONS

This application claims the benefit under 35 U.S.C. Section 119 of Korean Patent Application Serial No. 10-2014-0070914, entitled “Circuit Board and Method of Manufacturing the Same” filed on Jun. 11, 2014, which is hereby incorporated by reference in its entirety into this application.

### BACKGROUND OF THE INVENTION

1. Technical Field

The present invention relates to a circuit board.

2. Description of the Related Art

Generally, electronic components, external devices, or the like, connected to a circuit board are electrically connected to connection pads formed on the circuit board in a wire bonding scheme, or the like.

Recently, electronic products have been miniaturized, thinned, and densified. In accordance with this trend, an effort to decrease a pitch between the connection pads or improve a degree of integration of the connection pads. Meanwhile, the wider the width of the connection pad, the more advantageous in improving reliability of coupling such as wire bonding, or the like.

On the other hand, in order to prevent oxidation of the connection pad and improve coupling reliability, a plating layer has been formed using nickel, gold, or the like. To this end, a separate plating lead wire has been required. However, in the case in which the plating lead wire remains in a final product, it may cause noise and limit a circuit design.

### RELATED ART DOCUMENT

### Patent Document

(Patent Document 1) US 2001-0035452 A1

### SUMMARY OF THE INVENTION

An object of the present invention is to provide a method of manufacturing a circuit board capable of forming a plating layer on a surface of a connection pad without a plating lead wire.

Another object of the present invention is to provide a method of manufacturing a circuit board capable of efficiently manufacturing a circuit board having decreased noise.

Still another object of the present invention is to provide a circuit board capable of improving a degree of integration of connection pads for connection with external devices and maximally securing a width of the connection pads.

Objects of the present invention are not limited to the above-mentioned objects. That is, other objects that are not mentioned may be obviously understood by those skilled in the art to which the present invention pertains from the following description.

In a method of manufacturing a circuit board according to an exemplary embodiment of the present invention, a seed layer and a resist layer may be formed on a solder resist layer, and the resist layer may be patterned to form connection pads and pad plating layers. Then, the resist layer may be removed, and the seed layer exposed to the outside may be removed.

In a circuit board according to an exemplary embodiment of the present invention, pad plating layers may be provided on upper surfaces of connection pads exposed through an opening part of a solder resist layer.

### BRIEF DESCRIPTION OF THE DRAWINGS

FIG. 1 is a view schematically showing a circuit board according to an exemplary embodiment of the present invention and an electronic component including the circuit board;

FIG. 2 is a perspective view schematically showing the circuit board according to an exemplary embodiment of the present invention;

FIGS. 3A to 3I are perspective views showing processes for describing a method of manufacturing a circuit board according to an exemplary embodiment of the present invention, wherein FIG. 3A schematically shows a state in which circuit patterns are formed on an insulating layer; FIG. 3B schematically shows a state in which a solder resist layer is formed; FIG. 3C schematically shows a state in which a seed layer is formed; FIG. 3D schematically shows a state in which a resist layer is formed; FIG. 3E schematically shows a state in which the resist layer is patterned; FIG. 3F schematically shows a state in which connection pads are formed; FIG. 3G schematically shows a state in which pad plating layers are formed; FIG. 3H schematically shows a state in which the resist layer and the seed layer are removed; and FIG. 3I schematically shows a state in which portions of surfaces of the connection pads are surface-treated.

### DESCRIPTION OF THE PREFERRED EMBODIMENTS

Various advantages and features of the present invention and methods accomplishing them will become apparent from the following description of exemplary embodiments with reference to the accompanying drawings. However, the present invention is limited to exemplary embodiments set forth herein, but may be modified in many different forms. These exemplary embodiments may be provided so that the scope of the present invention will be thorough and complete, and will fully convey the scope of the invention to those skilled in the art. Like reference numerals throughout the description denote like elements.

Terms used in the present specification are for explaining exemplary embodiments rather than limiting the present invention. Unless explicitly described to the contrary, a singular form includes a plural form in the present specification. The word “comprise” and variations such as “comprises” or “comprising,” will be understood to imply the inclusion of stated constituents, steps, operations and/or elements but not the exclusion of any other constituents, steps, operations and/or elements.

For simplification and clearness of illustration, a general configuration scheme will be shown in the accompanying drawings, and a detailed description of the feature and the technology well known in the art will be omitted in order to prevent a discussion of exemplary embodiments of the present invention from being unnecessarily obscure. Additionally, components shown in the accompanying drawings are not necessarily shown to scale. For example, sizes of some components shown in the accompanying drawings may be exaggerated as compared with other components in order to assist in understanding of exemplary embodiments of the present invention. Like reference numerals on different drawings will denote like components, and similar reference numerals on different drawings will denote similar components, but are not necessarily limited thereto.

In the specification and the claims, terms such as “first”, “second”, “third”, “fourth”, and the like, if any, will be used to distinguish similar components from each other and be used to describe a specific sequence or a generation sequence, but is not necessarily limited thereto. It may be understood that these terms are compatible with each other under an appropriate environment so that exemplary embodiments of the present invention to be described below may be operated in a sequence different from a sequence shown or described herein. Likewise, in the present specification, in the case in which it is described that a method includes a series of steps, a sequence of these steps suggested herein is not necessarily a sequence in which these steps may be executed. That is, any described step may be omitted and/or any other step that is not described herein may be added to the method.

In the specification and the claims, terms such as “left”, “right”, “front”, “rear”, “top”, “bottom”, “over”, “under”, and the like, if any, do not necessarily indicate relative positions that are not changed, but are used for description. It may be understood that these terms are compatible with each other under an appropriate environment so that exemplary embodiments of the present invention to be described below may be operated in a direction different from a direction shown or described herein. A term “connected” used herein is defined as being directly or indirectly connected in an electrical or non-electrical scheme. Targets described as being “adjacent to” each other may physically contact each other, be close to each other, or be in the same general range or region, in the context in which the above phrase is used. Here, a phrase “in an exemplary embodiment” means the same exemplary embodiment, but is not necessarily limited thereto.

Hereinafter, a configuration and an acting effect of exemplary embodiments of the present invention will be described in more detail with reference to the accompanying drawings.

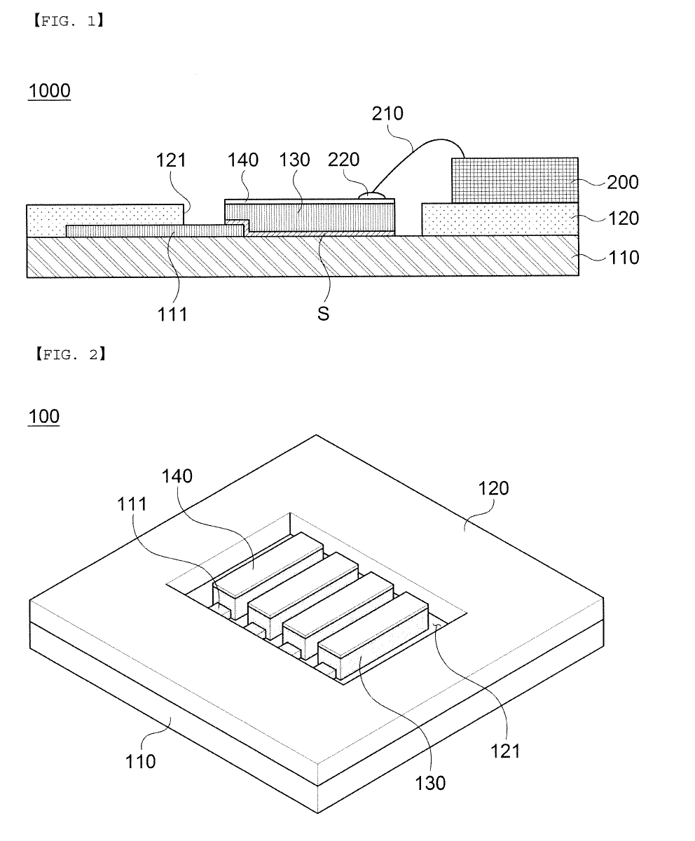

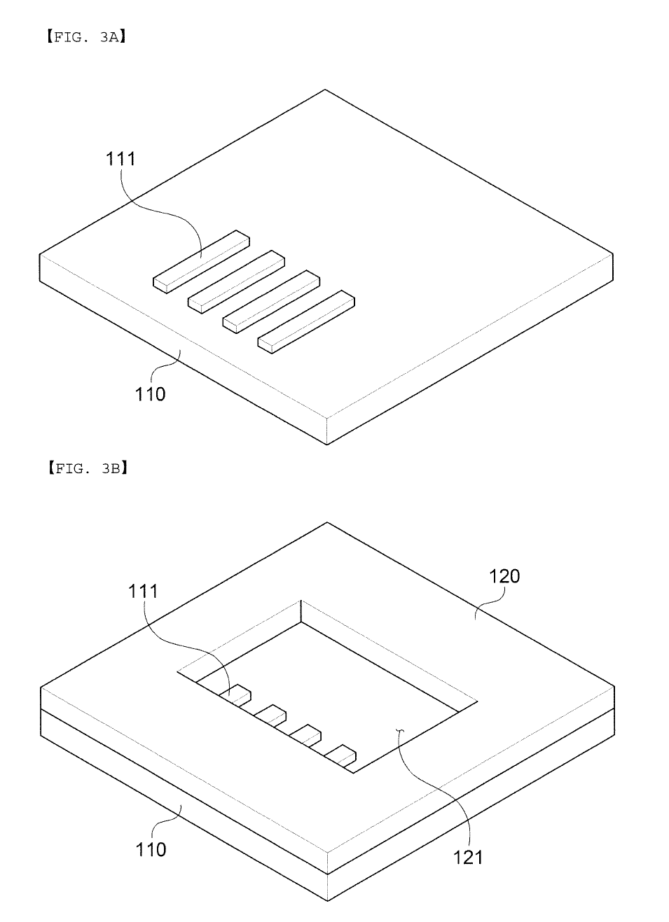

FIG. 1 is a view schematically showing a circuit board 100 according to an exemplary embodiment of the present invention and an electronic component 1000 including the circuit board 100; and FIG. 2 is a perspective view schematically showing the circuit board 100 according to an exemplary embodiment of the present invention.

Referring to FIGS. 1 and 2, the circuit board 100 according to an exemplary embodiment of the present invention includes a solder resist layer 120 and connection pads 130.

In an exemplary embodiment of the present invention, the solder resist layer 120 is provided on an insulating layer 110 having circuit patterns 111 formed thereon to cover at least portions of the circuit patterns 111 and at least a portion of the insulating layer 110.

Although the case in which only the insulating layer 110 and the circuit patterns 111 are provided below the solder resist layer 120 has been shown in FIGS. 1 and 2, insulating layers may be additionally provided, if necessary, and wiring patterns may be formed on one surface, both surfaces, an inner portion, or the like, of these insulating layers. In addition, an insulating layer having an active element or a passive element may also be provided. However, even in this case, the solder resist layer 120 may be implemented on the outermost layer of the circuit board 100.

Therefore, the solder resist layer 120 may serve to protect the circuit patterns 111 and the insulating layer 110. For example, the solder resist layer 120 may prevent a phenomenon that the circuit patterns 111 formed on the insulating layer 110 are exposed to the outside to thereby be polluted. In addition, even though a device 200 is mounted on the circuit board 100, the circuit patterns 111 on the insulating layer 110 are not affected, for example, are not damaged. Further, in the case in which a solder 220, or the like, is used in order to electrically connect the device 200 and the connection pad 130, a phenomenon that the circuit pattern 111 is polluted by the solder 220, or the like, and adjacent circuit patterns 111 are unintentionally connected to each other by the solder 220, or the like, may be prevented.

Meanwhile, the solder resist layer 120 is provided with an opening part 121. In an exemplary embodiment of the present invention, at least the portions of the circuit patterns 111 are exposed through the opening part 121. Connection pads 130 to be described below contact at least the portions of the circuit patterns 111 exposed through the opening part 121, thereby making it possible to implement physical and electrical connection.

Here, the connection pads 130 are exposed to the outside of the solder resist layer 120 through the opening part 121 of the solder resist layer 120. In an exemplary embodiment of the present invention, a plurality of connection pads 130 may be exposed to the outside through a single opening part 121. Further, in an exemplary embodiment of the present invention, all surfaces of the connection pad 130 except for a surface of the connection pad 130 contacting the insulating layer 110 among surfaces of the connection pad 130 may be exposed through the opening part 121.

An example in which a seed layer S is provided between the circuit pattern 111 and the connection pad 130 is shown in FIG. 1. Here, the seed layer S may serve as a seed for performing a plating process and may be made of a conductor material such as copper, or the like. In the case in which the seed layer S is made of copper as described above and the circuit pattern 111 and the connection pad 130 are also made of copper, a boundary between the seed layer S and the circuit pattern 111 or the connection pad 130 may not be apparent. In this regard, the seed layer S shown in FIG. 1 may be considered as a portion of the connection pad 130 or a portion of the circuit pattern 111. In addition, the seed layer S is not separately marked so as to be identified in FIG. 2.

In an exemplary embodiment of the present invention, a pad plating layer 140 is provided on an upper surface of the connection pad 130. The pad plating layer 140 is provided on only an upper surface of the connection pad 130 except for side surfaces of the connection pad 130. Here, in an exemplary embodiment of the present invention, the connection pad 130 is made of a conductive material such as copper, or the like. In addition, the pad plating layer 140 serves to prevent oxidation, pollution, or the like, of a surface of the connection pad 130 and allow a wire 210, the solder 220, or the like, to be tightly coupled to the connection pad 130. In an exemplary embodiment of the present invention, the pad plating layer 140 may be implemented by gold plating. If necessary, the pad plating layer 140 may also be implemented by nickel plating. Furthermore, the pad plating layer 140 may also be implemented by sequentially forming a nickel plating layer and a gold plating layer on the surface of the connection pad 130. In addition, the pad plating layer 140 may also be implemented by an alloy containing at least one of nickel and gold.

In an exemplary embodiment of the present invention, the pad plating layer 140 is formed on only the upper surface of the connection pad 130. That is, the pad plating layer 140 is not formed on the side surfaces of the connection pad 130. When comparing the case in which the pad plating layers are formed on the side surfaces of the connection pads 130 having the same width with the case in which the plating layers are not formed on the side surfaces of the connection pads 130 having the same width, the latter case is more advantageous in improving a degree of integration of the connection pads 130 as compared with the former case.

Therefore, the pad plating layers 140 are formed on only the upper surfaces of the connection pads 130 except for the side surfaces of the connection pads 130, thereby making it possible to maximize widths of the connection pads 130 and improve a degree of integration of the connection pads 130.

Meanwhile, portions on which the pad plating layer 140 is not formed, for example, the side surfaces of the connection pad 130 may be surface-treated by an organic material, or the like. Here, as the surface treatment, organic solderability preservative treatment, brown oxide treatment, or the like, may be used.

In an exemplary embodiment of the present invention, the device 200 such as a memory chip, or the like, may be directly or indirectly coupled to the solder resist layer 120.

In addition, the device 200 may be provided with a connection terminal (not shown), and the connection terminal and the connection pad 130 may be electrically connected to each other. In an exemplary embodiment of the present invention, the connection terminal and the connection pad 130 may be connected to each other by the wire 210 having one end connected to the connection terminal and the other end connected to the connection pad 130. In addition, the solder 220 may be used in order to fix the wire 210 to the connection pad 130.

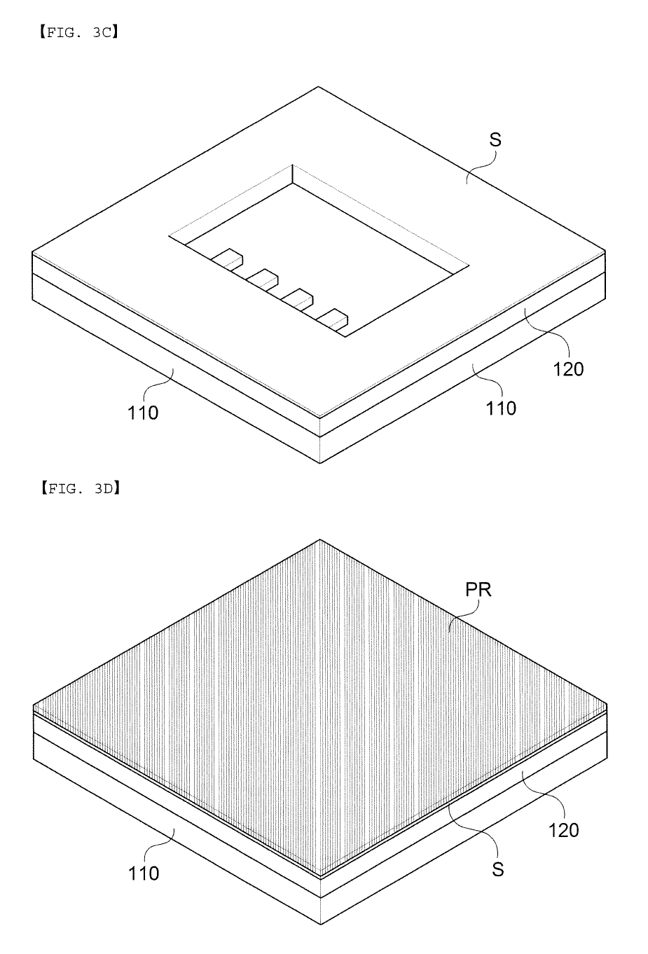

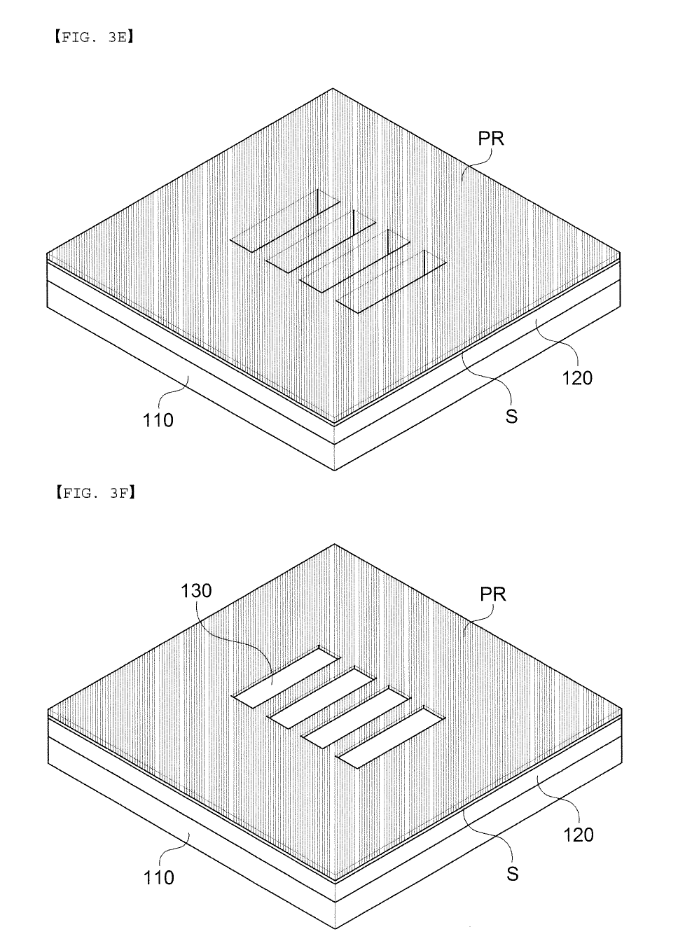

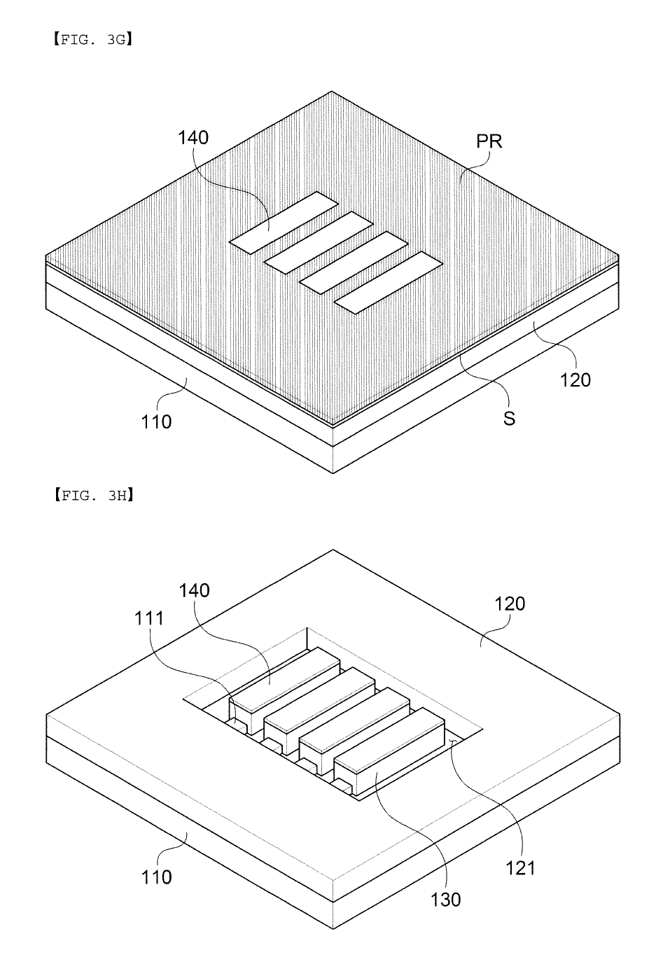

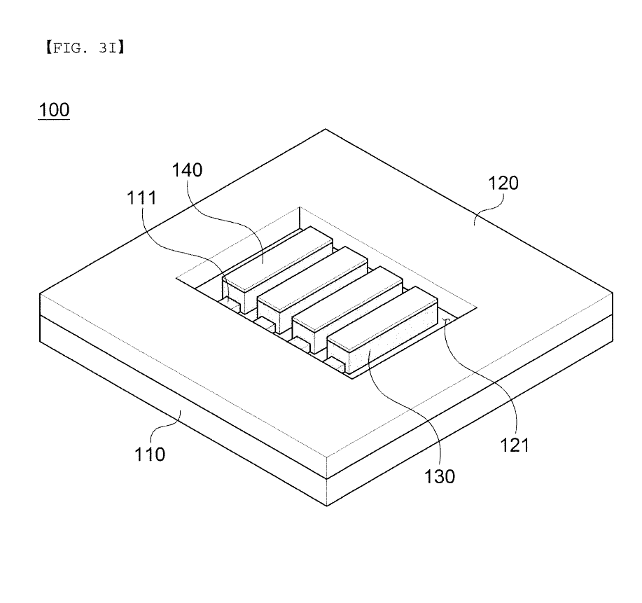

FIGS. 3A to 3I are perspective views showing processes for describing a method of manufacturing a circuit board 100 according to an exemplary embodiment of the present invention.

Referring to FIGS. 3A to 3I, in the method of manufacturing a circuit board 100 according to an exemplary embodiment of the present invention, the seed layer S is formed on the solder resist layer 120, a resist layer PR covering the seed layer S is formed, and the resist layer PR is patterned to form the connection pads 130. In an exemplary embodiment of the present invention, after the pad plating layers 140 are formed on the upper surfaces of the connection pads 130, the resist layer PR and the seed layer S may be removed.

First, the circuit patterns 111 are formed on the insulating layer 110, as shown in FIG. 3A.

Next, the solder resist layer 120 covering the insulating layer 110 and the circuit patterns 111 is formed, as shown in FIG. 3B. Here, the opening part 121 is formed in the solder resist layer 120, and at least portions of the circuit patterns 111 may be exposed by the opening part 121.

Next, the seed layer S is formed, as shown in FIG. 3C. Here, the seed layer S covers a surface of the solder resist layer 120 and an inner side of the opening part 121. In an exemplary embodiment of the present invention, the portions of the circuit patterns 111 may be exposed by the opening part 121, and the seed layer S may also cover the circuit patterns 111 exposed as described above.

Next, the resist layer PR is formed so as to cover the seed layer S, as shown in FIG. 3D. Here, the resist layer PR is formed using a liquid resist, such that the resist may be filled up to the inner side of the opening part 121.

Next, the resist layer PR is patterned, as shown in FIG. 3E. The resist in regions in which the connection pads 130 are to be formed is removed through this patterning. Therefore, the seed layer S in the regions in which the connection pads 130 are to be formed is exposed. In an exemplary embodiment of the present invention, this patterning process may be performed by exposure and development. In addition, the regions in which the resist is removed by the patterning process may be overlapped with the opening part 121 described above. In an exemplary embodiment of the present invention, the portions of the circuit patterns 111 may be exposed through the opening part 121, and at least a portion of the portions of the circuit patterns 111 exposed through the opening part 121 may be overlapped with a region in which the resist is removed by the patterning process. Therefore, when a subsequent process is performed, the portions of the connection pads 130 may contact the portions of the circuit patterns 111 described above.

Next, the connection pads 130 are formed, as shown in FIG. 3F. Here, a process of forming the connection pads 130 may be performed in a plating scheme. That is, the connection pads 130 may be formed by filling conductive materials in at least portions in the resist layer PR.

Next, the pad plating layers 140 are formed on the upper surfaces of the connection pads 130, as shown in FIG. 3G, and the resist layer PR and the seed layer S are removed, as shown in FIG. 3H. In an exemplary embodiment of the present invention, after the connection pads 130 are formed, a process of forming the pad plating layers 140 in a state in which the resist layer PR is not removed is performed. Therefore, the pad plating layers 140 are formed on only the upper surfaces of the connection pads 130, and are not formed on the side surfaces of the connection pads 130. In an exemplary embodiment of the present invention, the pad plating layer 140 may be formed in an electroplating scheme. Here, since power may be directly applied to the seed layer S, a separate plating lead wire does not need to be provided. In addition, a separate process for removing the plating lead wire does not need to be performed. In a situation in which a signal transfer speed is rapidly increased, the plating lead wire is a factor causing noise. Therefore, in the case in which the plating lead wire is required in a manufacturing process, a separate process of removing the plating lead wire needs to be performed in a final product. However, according to an exemplary embodiment of the present invention, the separate plating lead wire is not required, such that the separate process of removing the plating lead wire does not need to be performed. Furthermore, since the plating lead wire does not need to be considered in a circuit design process, a degree of freedom in a design may be improved.

Next, the exposed surfaces of the connection pads 130, for example, the side surfaces of the connection pads 130, or the like, may be surface-treated by the organic material, or the like, as described above, as shown in FIG. 3I. In an exemplary embodiment of the present invention, in the case in which the portions of the circuit patterns 111 are exposed through the opening part 121, the exposed portions of the circuit patterns 111 may also be surface-treated.

According to an exemplary embodiment of the present invention, the plating layer may be formed on the surface of the connection pad without the plating lead wire.

According to an exemplary embodiment of the present invention, the circuit board having decreased noise may be efficiently manufactured.

According to an exemplary embodiment of the present invention, a degree of integration of the connection pads for connection with external devices may be improved, and a width of the connection pads may be maximally secured.

What is claimed is:

1. A method of manufacturing a circuit board, comprising:
forming a seed layer on an upper surface of a solder resist layer;
forming a resist layer on an upper surface of the seed layer;
forming connection pads using a first metal in a state in which the resist layer is patterned so that portions of the seed layer are exposed;
forming pad plating layers using a second metal different from the first metal on upper surfaces of the connection pads; and
removing the resist layer and the seed layer after forming the connection pads.

2. The method of manufacturing a circuit board according to claim 1, wherein a surface of the connection pad exposed from the pad plating layer among surfaces of the connection pad is surface-treated using an organic material.

3. A method of manufacturing a circuit board, comprising:
forming a solder resist layer covering an upper surface of an insulating layer having circuit patterns formed on at least portions of the upper surface thereof and the circuit patterns;
forming an opening part in the solder resist layer, the opening part exposing regions in which connection pads are to be formed on the upper surface of the insulating layer and at least portions of the circuit patterns;
forming a seed layer covering an upper surface of the solder resist layer and the regions exposed by the opening part;
forming a resist layer covering the seed layer and exposing the seed layer in the regions in which the connection pads are to be formed;
forming the connection pads using a first metal;
forming pad plating layers made of a second material different from the first metal; and
removing the seed layer and the resist layer present in regions except for regions below the connection pads.

4. The method of manufacturing a circuit board according to claim 3, wherein a surface of the connection pad exposed from the pad plating layer among surfaces of the connection pad is surface-treated using an organic material.

5. A circuit board comprising:
an insulating layer including circuit patterns and connection pads provided on an upper surface thereof;
a solder resist layer provided with an opening part exposing at least portions of the circuit patterns and the connection pads; and
pad plating layers provided on only upper surfaces of the connection pads except for side surfaces of the connection pads, the pad plating layers being made of a conductive material different from a material configuring the connection pads.

6. The circuit board according to claim 5, wherein a surface of the connection pad exposed from the pad plating layer among surfaces of the connection pad is surface-treated using an organic material.

7. The circuit board according to claim 6, wherein the pad plating layer is made of at least one of nickel and gold or is made of an alloy containing at least one of the nickel and the gold.
